(19) United States
(12) Patent Application Publication
(10) Pub. No.: US 2021/0159157 A1
(43) Pub. Date: May 27, 2021

(54) SEMICONDUCTOR CLIP AND RELATED METHODS

(71) Applicant: SEMICONDUCTOR COMPONENTS INDUSTRIES, LLC, Phoenix, AZ (US)

(72) Inventors: Keunhyuk LEE, Suzhou (CN); Tiburcio MALDO, Consolacion (PH); Jerome TEYSSEYRE, Scottsdale, AZ (US); ZhengQiao XU, Suzhou (CN); Zhiling LIU, Suzhou (CN)

(73) Assignee: SEMICONDUCTOR COMPONENTS INDUSTRIES, LLC, Phoenix, AZ (US)

(21) Appl. No.: 16/695,582

(22) Filed: Nov. 26, 2019

(51) Int. Cl. H01L 23/498; H01L 23/00; H01L 21/48; H01L 21/56

(52) U.S. Cl. CPC H01L 23/49838; H01L 23/49861; H01L 23/49811; H01L 2021/60195; H01L 24/45; H01L 21/4853; H01L 21/565; H01L 23/49827

(57) ABSTRACT

Implementations of semiconductor clips may include a die attach portion coupled to a step portion, a lead attach portion directly coupled to the step portion, a first alignment feature directly coupled to a first side of the lead attach portion, and a second alignment feature directly coupled to a second side of the lead attach portion. The second side may be opposite the first side. The lead attach portion may be in a plane substantially parallel with a plane formed by the die attach portion.

### BACKGROUND

### 1. Technical Field

Aspects of this document relate generally to semiconductor packages that utilize a clip for electrical connection to a device. More specific implementations involve clip-containing semiconductor packages for die.

### 2. Background

Clips, which are often copper, are used in semiconductor packages to provided electrical connections in semiconductor package. The clips are used as an alternative to wire bonding. Clips can also be used to improve thermal performance of a semiconductor package.

### SUMMARY

Implementations of semiconductor clips may include a die attach portion coupled to a step portion, a lead attach portion directly coupled to the step portion, a first alignment feature directly coupled to a first side of the lead attach portion, and a second alignment feature directly coupled to a second side of the lead attach portion. The second side may be opposite the first side. The lead attach portion may be in a plane substantially parallel with a plane formed by the die attach portion.

Implementations of semiconductor clips may include one, all, or any of the following:

An entirety of the lead attach portion may be planar.

The die attach portion may include one or more openings therethrough.

The first alignment feature and the second alignment feature may extend substantially perpendicularly from the lead attach portion.

Implementations of a semiconductor package may include a die coupled over a lead frame, a lead including one of two openings or two notches, and a clip. The clip may include a die attach portion coupled to a lead attach portion, a first alignment feature coupled to a first side of the lead attach portion, and a second alignment feature coupled to a second side of the lead attach portion. The second side may be opposite the first side. The die attach portion may be coupled over the die. The lead attach portion may be coupled over the lead. The first alignment feature and the second alignment feature may be coupled within one of the two openings or the two notches.

Implementations of semiconductor packages may include one, all, or any of the following:

The lead attach portion may be planar.

The semiconductor package may include a mold compound coupled over the clip and the lead frame.

The lead may include a plurality of grooves in the side of the lead configured to be coupled to the clip.

The lead may include one or more recesses therein.

The lead attach portion may be in a first plane substantially parallel with a second plane formed by the die attach portion.

The first alignment feature and the second alignment feature may extend substantially perpendicularly from the lead attach portion.

The die may include silicon carbide.

The lead attach portion may be welded to the lead through ultrasonic clip welding.

The semiconductor package may include a bond wire bonded to the die and to a second lead.

Implementations of methods of forming a semiconductor package may include stamping a frame comprising a clip, trimming two or more tie bars coupled to the clip to separate the clip from the frame, forming two or more alignment features through bending a portion of the two or more tie bars substantially perpendicularly to a plane of a lead attach portion of the clip, and coupling the clip over a die and over a lead.

Implementations of methods of forming a semiconductor package may include one, all, or any of the following:

The method may include inserting the two or more alignment features into one of two notches or two openings in the lead, and bonding the clip to the die and the lead.

Bonding the clip to the lead may include welding the clip to the lead using an ultrasonic pressing tool.

The method may include stamping the frame no more than a single time.

The method may include applying a mold compound over the clip and the lead.

The lead attach portion of the clip may be in a first plane parallel to a second plane formed by a die attach portion of the clip.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a perspective and partially see-through view of a semiconductor package is illustrated;

FIG. 2 is an exploded view of the semiconductor package of FIG. 1;

FIG. 3 is a side and partially see-through view of the semiconductor package of FIG. 1;

FIG. 4 is a perspective view of the clip of the semiconductor package of FIG. 1;

FIG. 5 is a perspective view of a portion of the leads of the semiconductor package of FIG. 1;

FIG. 6 is a view of the portion of the leads frame of FIG. 5 covered by a mold compound;

FIG. 7 is a perspective view of the clip of FIG. 4 coupled to the portion of the leads frame of FIG. 5;

FIG. 8 is a perspective view of a bond wire bonded to a die;

FIG. 9 is a perspective view of a second implementation of a clip coupled to a lead frame;

FIG. 10 is a side view of a clip coupled to a lead frame in an ultrasonic pressing tool;

FIG. 11 is a perspective view of a lead;

FIG. 12 is a perspective view of a second implementation of a lead;

FIG. 13 is a perspective view of frame comprising a plurality of clips;

FIG. 14 is a perspective view of a portion of a lead frame;

FIG. 15 is a perspective view of the lead frame of FIG. 14 having a die coupled thereto;

FIG. 16 is a perspective view of lead frame and die of FIG. 15 having solder dispensed thereon;

FIG. 17 is a perspective view of the lead frame and die of FIG. 16 coupled together through a clip;

FIG. 18 is a perspective view of the lead frame and die of FIG. 17 with a wire coupling the die to the lead frame; and

FIG. 19 is a perspective and semi-transparent view of a mold compound coupled over the lead frame and die of FIG. 18.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages and clips will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages and clips, and implementing components and methods, consistent with the intended operation and methods.

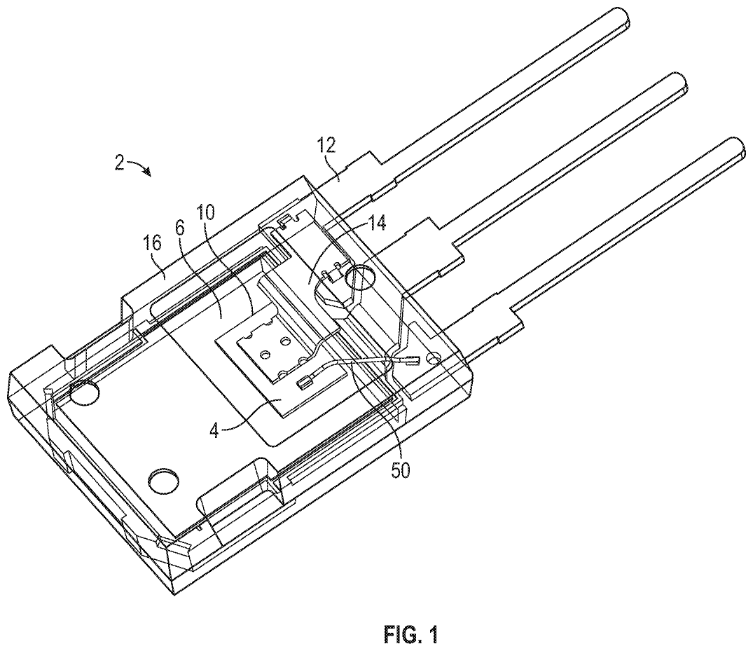

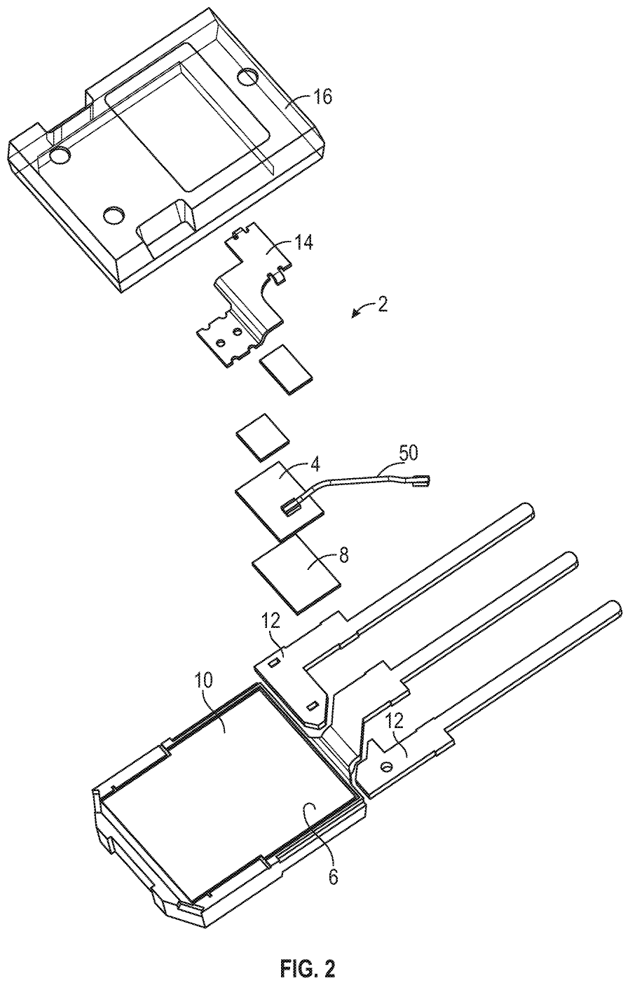

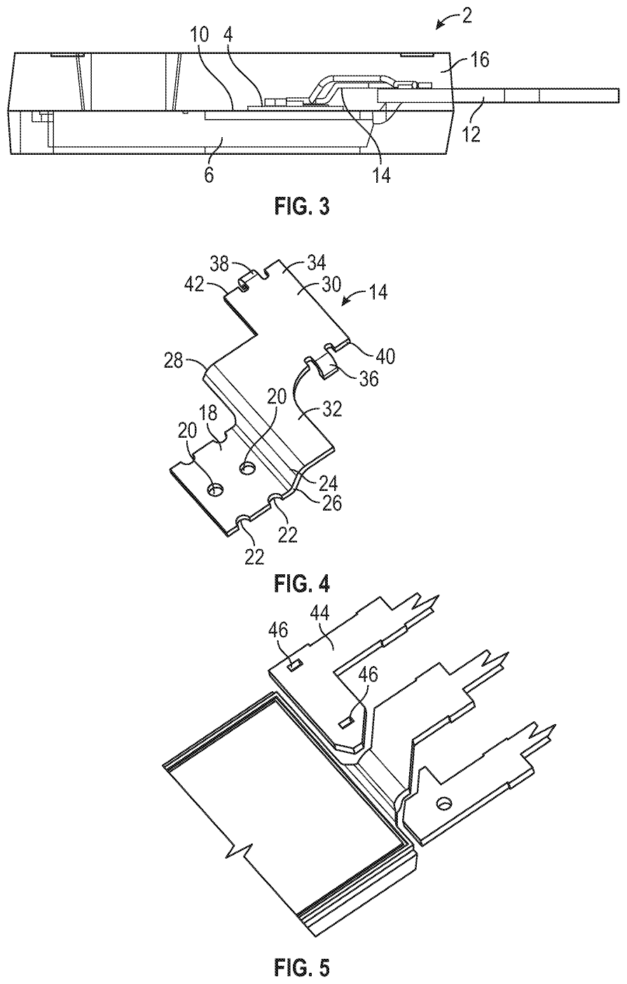

Referring to FIG. 1, a perspective and partially see-through view of a semiconductor package is illustrated. FIG. 2 is an illustration of an exploded view of the semiconductor package of FIG. 1, and FIG. 3 is a side and partially see-through view of the semiconductor package of FIG. 1. As illustrated by FIGS. 1-3, in various implementations the semiconductor package 2 may be configured to be used in electric and hybrid electric vehicles. In other implementations, the semiconductor package may be configured for use with a non-electric or hybrid electric vehicle or a non-vehicle. In particular implementations, the semiconductor package 2 may include, by non-limiting example, a power train inverter, a DC-DC converter, or an on-board charger. In other implementations, the semiconductor package 2 may be another type of semiconductor package. As illustrated by FIGS. 1-3, the semiconductor package may include a die 4 coupled over a lead frame 6. In various implementations, the die may include silicon carbide (SiC). In other implementations, the die may include another silicon based semiconductor material or non-silicon based semiconductor material. As illustrated by FIG. 2, in various implementations the die 4 may be coupled to the lead frame 6 through solder 8, though in other implementations other adhesives or die bonding materials could be used to couple the die to the lead frame.

As illustrated by FIGS. 1-3, the lead frame may be down set, meaning that the die attach portion 10 of the lead frame 6 is set off in a separate plane, or not aligned, with the leads 12. As illustrated in the orientation of FIGS. 1-3, the die attach portion is set downwards from the leads 12. While the implementations disclosed herein primarily refer to down set lead frames, it is understood that other implementations may include lead frames that are not down set, including implementations where the die attach portion of the lead frame and the leads are in the same plane or in a plane above the leads.

In various implementations, a clip 14 is coupled to both the die 4 and to at least one of the leads 12. In various implementations, the clip 14 may be coupled to the die 4 and/or at least one of the leads through a solder or adhesive. In other implementations, the clip 14 may be welded to the lead. As illustrated by FIGS. 1-3, in various implementations the semiconductor package may also include a bond wire 50 bonded between the die 4 and the leads 12. In various implementations, the semiconductor package may include a mold compound 16 coupled over the lead frame 6 and/or clip 14. In particular implementations, the mold compound 16 may be an epoxy mold compound.

In the implementations of the semiconductor packages disclosed herein, the clip 14 may be self-aligning. In such self-aligning implementations, rotation of the clip relative to the leads may be prevented. Referring to FIG. 4, a perspective view of the clip of the semiconductor package of FIG. 1 is illustrated. In various implementations, the clip may include, by non-limiting example, copper, aluminum, any other metal or conductive material, alloys thereof, and any combination thereof. The clip 14 includes a die attach portion 18 configured to couple to the die 4. In various implementations, the die attach portion 18 may include one or more openings 20 therethrough. As illustrated, the die attach portion may also include one or more notches 22 in the sidewall of the die attach portion 18. In various implementations, the perimeter of the die attach portion 18 may include a variety of shapes and sizes and reentrant openings therein. In particular implementations, the perimeter of the die attach portion 18 may be substantially the same size and/or shape as the perimeter of the die the die attach portion is configured to couple to. In other implementations, the perimeter of the die attach portion may be larger or smaller than the perimeter of the die the die attach portion is configured to couple to.

In implementations of semiconductor packages having a down set lead frame, the clip 14 may include a step portion 24 coupled to the die attach portion 18. In particular implementations, the step portion 24 may be directly coupled to the die attach portion 18. The height of the step portion 24 may be configured to allow the clip 14 to be coupled to both the die 4 and a lead 12 of the semiconductor package. In various implementations, the angle between the step portion and the die attach portion may be 90 degrees. In other implementations, the angle between the step portion and the die attach portion, as illustrated by FIG. 4, may be more than 90 degrees. As illustrated by FIG. 4, in various implementations the width of the step portion may be greater than the width of the die attach portion. As used herein, width refers to the distance between the first side 26 of the step portion 24 and the second side 28 of the step portion 24. In turn, the width of die attach portion 18, lead attach portion, 30, or clip 14 may be the distance between sides of the die attach portion, lead attach portion, or clip corresponding to the first side 26 and the second side 28. As illustrated by FIG. 4, the die attach portion 18 may not be centered along the width of the step portion 24. In other implementations, the die attach portion 18 may be centered along a width of the step portion 24.

Still referring to FIG. 4, the clip 14 includes a lead attach portion 30 coupled to the step portion 24. The lead attach portion 30 is configured to couple over a lead of a semiconductor package. In various implementations, the entirety of the lead attach portion is planar. In other implementations, the lead attach portion 30 may not be entirely planar. In various implementations, as illustrated, the lead attach portion 30 is in a plane substantially parallel with a plane formed by the die attach portion 18. In other implementations, the lead attach portion 30 may not be in a plane parallel to a plane formed by the die attach portion 18. As illustrated by FIG. 4, the width of the lead attach portion 30 may form a stepped shape, with a first portion 32 of the lead attach portion 30 aligned with the step portion 24 and a second portion 34 of the lead attach portion 30 offset from the first portion 32. In such implementations, the particular shape of the lead attach portion 30 may increase the overall width of the clip 14.

As illustrated by FIG. 4, the clip 14 may include a length perpendicular to the width that is substantially the same as or less than the width of the clip. In such implementations, the short length and wide design of the clip 14 may lower the inductance within the semiconductor package. Further, the large contact area of the clip coupled to the lead may also lower the inductance of the semiconductor package. Similarly, just as the width and length of the clip 14 may be configured to obtain higher electrical performance, the thickness of the clip may also be a thickness configured to obtain a particular electrical performance.

Still referring to FIG. 4, a first alignment feature 36 may be coupled, and may be directly coupled, to a first side 40 of the lead attach portion 30. In various implementations, only a single alignment feature may be coupled to the clip 14. In other implementations, as is illustrated by FIG. 4, a second alignment feature 38 may be coupled, and may, in various implementations, be directly coupled, to a second side 42 of the lead attach portion 30. The second side 42 may be opposite the first side 40. In still other implementations, more than two alignment features may be coupled to the clip 14.

As illustrated by FIG. 4, in various implementations the first alignment feature 36 and the second alignment feature 38 may extend substantially perpendicularly from the lead attach portion 30. The first alignment feature 36 and the second alignment feature 38 may be configured to align the clip 14 through engaging within an opening, notch, or recess included in the lead.

Referring back to FIGS. 1-3, the lead frame includes one or more leads 12. Referring to FIG. 5, a perspective view of a portion of the leads of the semiconductor package of FIG. 1 are illustrated. In particular implementations, the leads 12 may include only three leads, though in other implementations the leads 12 may include more or less than three leads. As illustrated, a first lead 44 of the leads 12 may include one or more openings 46 corresponding to the number of alignment features coupled to the lead attach portion. As illustrated by FIG. 5, the first lead 44 includes two openings configured to receive the first alignment feature 36 and the second alignment feature 38 coupled to the lead attach portion 30. In various implementations, the openings 46 may extend entirely through the first lead 44 or may extend only partially through the first lead 44. In other implementations, and as later disclosed herein, the first lead may include one or more notches rather than the openings 46 that are configured to receive the alignment features coupled to the clip.

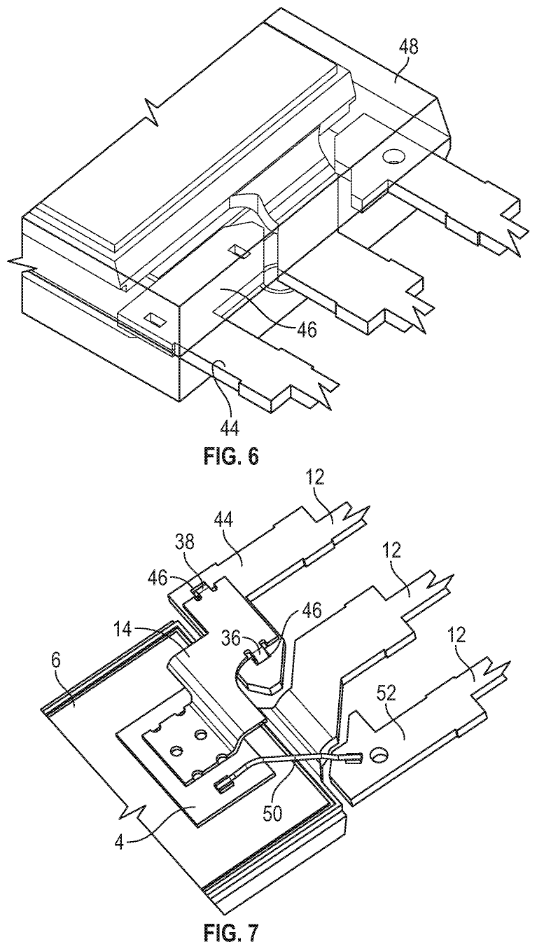

Referring to FIG. 6, a view of the portion of the leads of FIG. 5 covered by a mold compound is illustrated. In various implementations, the openings 46 or notch in any of the leads may also be considered locking mechanisms as they may be configured to lock the mold compound 48 to the leads 12. In such implementations, the locking mechanisms may prevent delamination of any of the semiconductor packages disclosed herein.

Referring to FIG. 7, a perspective view of the clip of FIG. 4 coupled to the portion of the leads of FIG. 5 is illustrated. As illustrated, in various implementations of semiconductor packages the die attach portion 18 of the clip 14 is coupled over the die 4 and the lead attach portion 30 of the clip 14 is coupled over a first lead 44 of the leads. In various implementations, and as illustrated by FIG. 7, the first alignment feature 36 and the second alignment feature 38 are coupled within the openings 46 in the first lead 44. In such implementations, the first alignment feature 36 and the second alignment feature 38 may prevent rotation of the clip relative to the leads 12. Further, the first alignment feature 36 and the second alignment feature 38 may also prevent lateral movement of the clip 14. In such implementations, an alignment jig may not be necessary to align the clip with the first lead 44.

Still referring to FIG. 7, in various implementations a bond wire 50 may be bonded between the die 4 and a second lead 52. In particular implementations, the bond wire 50 may be a gate wire. In other implementations, the bond wire 50 may be bonded between the die 4 and the first lead 44. In still other implementations, the semiconductor package may not include any bond wires, depending on the structure of the particular die included.

In the various implementations of semiconductor packages disclosed herein, a higher current rating and a lower inductance may be achieved through use of the implementations of the clips disclosed herein as compared to a semiconductor package utilizing only wire bonds. Further, the self-aligning clip enables the semiconductor packages disclosed herein to utilize a clip as the alignment features of the clip eliminate rotation and lateral movement of the clip relative to the leads.

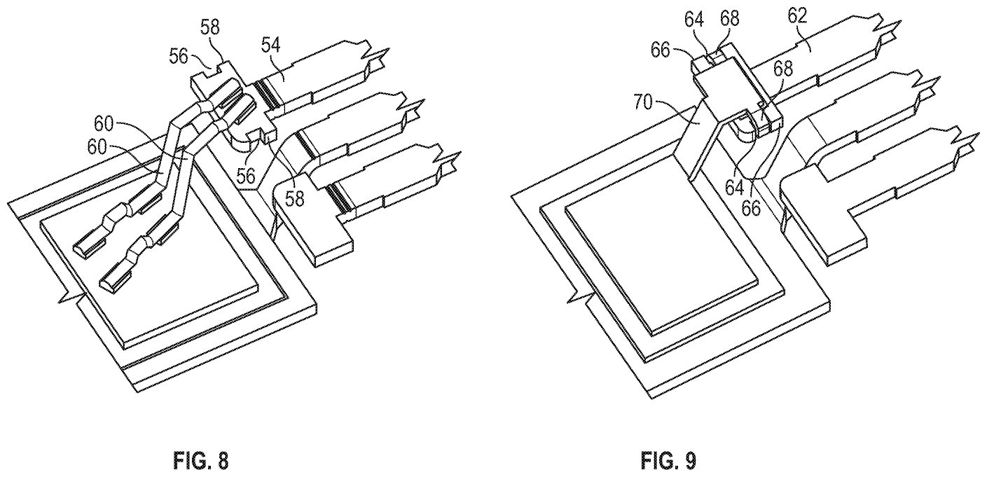

Referring to FIG. 8, a perspective view of a bond wire bonded to a die is illustrated. As illustrated by FIG. 8, in various implementations a lead 54 may include one or more notches 56 in one or more sidewalls 58 of the lead. The notches 56 may be configured to receive alignment features coupled to a clip in order to prevent rotation and movement of the clip, similar to what is illustrated by FIG. 9. However, in various implementations, as illustrated by FIG. 8, the semiconductor package may not include a clip but rather may include bond wires 60 in place of the clip. Accordingly, though the lead frame and leads may be designed in order to accommodate a clip, the lead frame and leads may also be utilized in packages not including a clip. In such implementations, the notches 56 may serve as mold locking mechanisms to a mold compound encapsulating a portion of the lead 54.

Referring to FIG. 9, a perspective view of a second implementation of a clip coupled to a lead frame is illustrated. In various implementations a lead 62 may include one or more notches 64 in one or more sidewalls 66 of the lead. The notches 64 may be configured to receive one or more alignment features 68 coupled to a clip 70 in order to prevent rotation and movement of the clip, similar to the implementations of the other implementations of clips disclosed herein. While FIG. 9 illustrates a particular shape of a clip, it is understood that the clip 70 may include any shape of any other clip disclosed herein, and in turn, the shape of the clip 70 may be incorporated into any other implementation of clips disclosed herein.

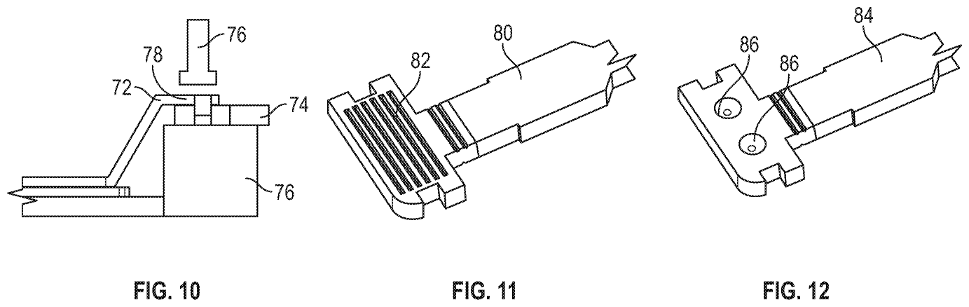

In the implementations of semiconductor packages disclosed herein, the lead attach portion of each clip may be coupled to the lead through a solder or adhesive. In other implementations, the lead attach portion of each clip may be coupled to the lead through other mechanisms. Referring to FIG. 10, a side view of a clip coupled to a lead frame in an ultrasonic pressing tool is illustrated. As illustrated, in various implementations the lead attach portion 78 of the clip 72 may be welded to the lead 74. In such implementations, an ultrasonic pressing tool 76 may be used to weld the clip 72 to the lead 74. In such implementations, the resistance between the clip 72 and the lead 74 may be reduced through removal of a solder or other bonding material.

Referring to FIG. 11, a perspective view of a lead is illustrated, and referring to FIG. 12, a perspective view of a second implementation of a lead is illustrated. As illustrated by FIG. 11, in various implementations a lead 80 may include one or more grooves 82. In such implementations, the one or more grooves may increase the bond line thickness (BLT) of a solder joint placed over the one or more grooves 82 and configured to bond a lead attach portion of a clip to the lead 80. In such implementations, the increased BLT may result in a more secure solder joint. Similarly, as illustrated by FIG. 12, in various implementations a lead 84 may include one or more recesses 86 therein. In such implementations, the one or more grooves may increase the BLT of a solder joint placed over the one or more recesses 86 and configured to bond a lead attach portion of a clip to the lead 84. In such implementations, the increased BLT may result in a more secure solder joint.

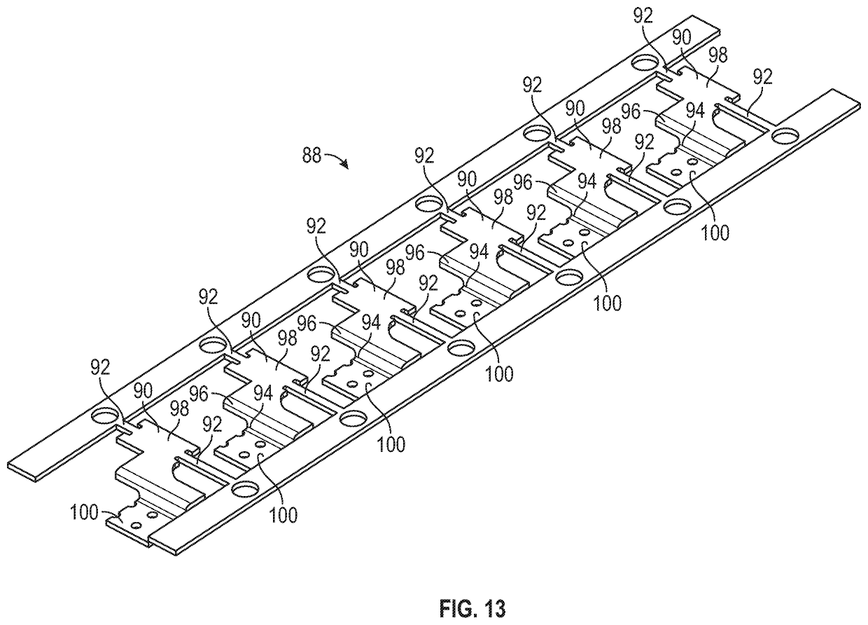

In various implementations, the method of forming a semiconductor package may include forming implementations of the self-aligning clips disclosed herein. Such methods may include stamping a frame including a plurality of clips. Referring to FIG. 13, a perspective view of a frame including a plurality of clips is illustrated. In various implementations, each clip of the plurality of clips 90 may be coupled to the remainder of the frame 88 through two tie bars 92 per clip. In various implementations, the method of forming a clip may include stamping the frame 88 a single time. Accordingly, each clip may include only a first bend 94 and a second bend 96 due to the single stamp. In other implementations, the method may include stamping the frame multiple times and forming more than two bends in each clip. In various implementations, after stamping the frame 88 each lead attach portion 98 of each clip 90 may be in a plane parallel to each die attach portion 100 of each clip.

After stamping the frame 88, the method of forming a clip may include separating each clip from the frame 88 through trimming each of the tie bars 92. Each of the tie bars may be trimmed at a length corresponding to a desired length of a corresponding alignment feature. In various implementations, the method may include forming two or more alignment features through bending a portion of the two or more tie bars coupled to each clip. In various implementations, each of the alignment features may be bent substantially perpendicularly to a plane of a lead attach portion of the clip.

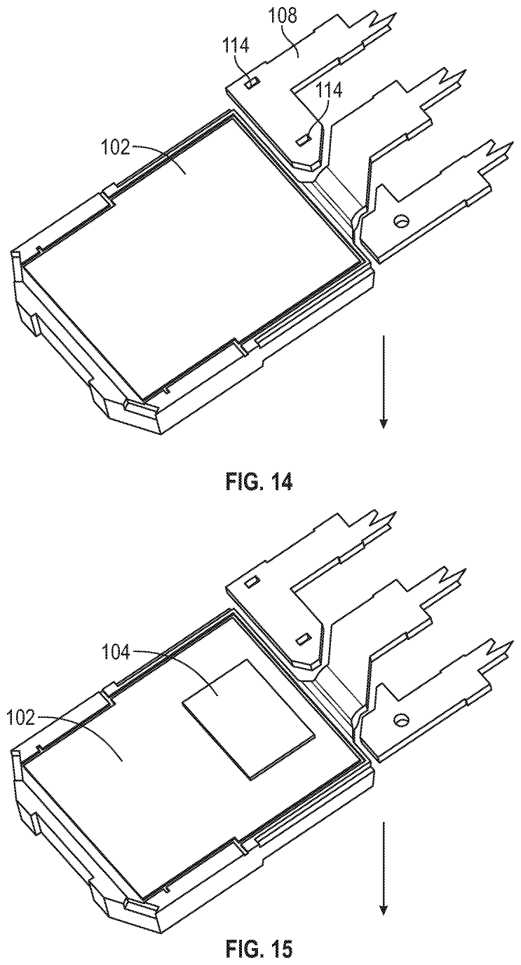

Referring to FIG. 14, a perspective view of a portion of a lead frame is illustrated. In various implementations, the method of forming a semiconductor package may include providing a lead frame 102 and forming one or more openings 114 or notches in a lead 108 of the lead frame. The lead frame 102 may be the same as or similar to any lead frame disclosed herein. Referring to FIG. 15, a perspective view of the lead frame of FIG. 14 having a die coupled thereto is illustrated. The method of forming the semiconductor package may include coupling a die 104 to the lead frame 102. The die 104 may be the same as or similar to any type of die disclosed herein. In various implementations the die 104 may be coupled to the lead frame through solder or another adhesive. In particular implementations where solder is used to couple the die 104 to the lead frame 102, the solder may include a lead solder.

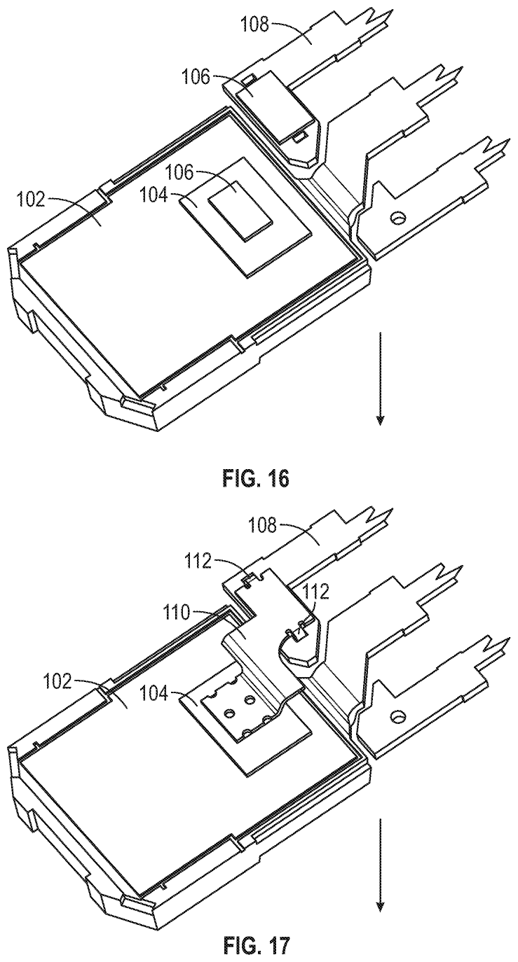

Referring to FIG. 16, a perspective view of the lead frame and die of FIG. 15 having solder dispensed thereon is illustrated. In various implementations, the method of forming a semiconductor package may include dispensing/printing/stencil printing solder 106 on the die and/or the lead 108. In other implementations, an adhesive may be used in place of the solder. In still other implementations, rather than dispensing solder or an adhesive over the lead, the clip may be coupled directly to the lead in implementations where the clip is welded to the lead. Such a weld may be an ultrasonic weld.

Referring to FIG. 17, a perspective view of the lead frame and die of FIG. 16 coupled together through a clip is illustrated. In various implementations, the method may include coupling the clip 110 over the die 104 and the lead 108. The clip may be coupled to the die through solder or an adhesive. The clip may also be coupled to the lead 108 through solder, an adhesive or a weld. The clip may be the same as or similar to any clip disclosed herein. In such implementations, the method may include inserting the alignment features 112 of the clip into the openings 114 or notches formed in the lead 108. In implementations where the clip is coupled to the die and/or lead through solder, the method may include reflowing the clip and lead frame to adhere the clip to the die and/or lead.

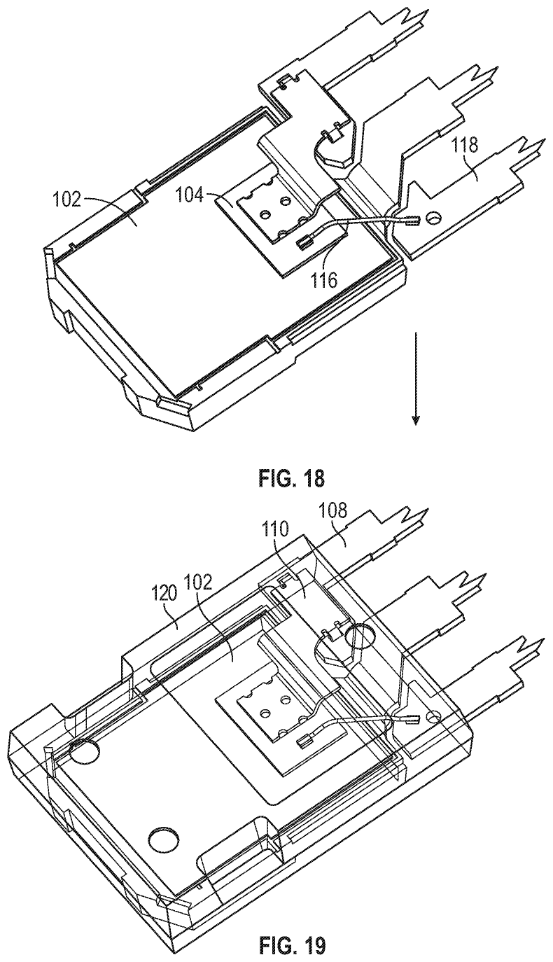

Referring to FIG. 18, a perspective view of the lead frame and die of FIG. 17 with a bond wire coupling the die to the lead frame is illustrated. In various implementations, the method may include coupling a bond wire 116 to the die 104 and a second lead 118 of the lead frame 102. In other implementations, no bond wires may be used in the method of forming the semiconductor package.

Referring to FIG. 19, a perspective and semi-transparent view of a mold compound coupled over the lead frame and die of FIG. 18 is illustrated. In various implementations, the method of forming a semiconductor package may include coupling a mold compound 120 over the clip 110 and the lead 108 of the lead frame 102. The mold compound may be any type of mold compound disclosed herein.

In places where the description above refers to particular implementations of semiconductor packages and clips and implementing components, sub-components, methods and sub-methods, it should be readily apparent that a number of modifications may be made without departing from the spirit thereof and that these implementations, implementing components, sub-components, methods and sub-methods may be applied to other semiconductor packages and clips.

1. A semiconductor clip comprising:
a die attach portion coupled to a step portion;
a lead attach portion directly coupled to the step portion;
a first alignment feature directly coupled to a first side of the lead attach portion; and
a second alignment feature directly coupled to a second side of the lead attach portion, wherein the second side is opposite the first side;
wherein the lead attach portion is in a plane substantially parallel with a plane formed by the die attach portion.

2. The semiconductor clip of claim 1, wherein an entirety of the lead attach portion is planar.

3. The semiconductor clip of claim 1, wherein the die attach portion includes one or more openings therethrough.

4. The semiconductor clip of claim 1, wherein the first alignment feature and the second alignment feature extend substantially perpendicularly from the lead attach portion.

5. A semiconductor package comprising:
a die coupled over a lead frame;
a lead comprising one of two openings or two notches; and
a clip comprising;
a die attach portion coupled to a lead attach portion;
a first alignment feature coupled to a first side of the lead attach portion; and
a second alignment feature coupled to a second side of the lead attach portion, the second side opposite the first side;
wherein the die attach portion is coupled over the die;
wherein the lead attach portion is coupled over the lead;
wherein the first alignment feature and the second alignment feature are coupled within one of the two openings or the two notches.

6. The semiconductor package of claim 5, wherein the lead attach portion is planar.

7. The semiconductor package of claim 5, further comprising a mold compound coupled over the clip and the lead frame.

8. The semiconductor package of claim 5, wherein the lead comprises a plurality of grooves in the side of the lead configured to be coupled to the clip.

9. The semiconductor package of claim 5, wherein the lead comprises one or more recesses therein.

10. The semiconductor package of claim 5, wherein the lead attach portion is in a first plane substantially parallel with a second plane formed by the die attach portion.

11. The semiconductor package of claim 5, wherein the first alignment feature and the second alignment feature extend substantially perpendicularly from the lead attach portion.

12. The semiconductor package of claim 5, wherein the die comprises silicon carbide.

13. The semiconductor package of claim 5, wherein the lead attach portion is welded to the lead through ultrasonic clip welding.

14. The semiconductor package of claim 5, further comprising a bond wire bonded to the die and to a second lead.

15-20. (canceled)
